(19) United States
(12) Patent Application Publication
(10) Pub. No.: US 2026/0173254 A1
(43) Pub. Date: Jun. 18, 2026

(54) CIRCUIT BOARD FOR CONNECTORS

(71) Applicant: Min Di Consultants Ltd., Hsinchu City (TW)

(72) Inventors: Min-Lin LEE, Hsinchu City (TW); Chi-Di LEE, Hsinchu City (TW)

(21) Appl. No.: 18/986,627

(22) Filed: Dec. 18, 2024

(51) Int. Cl. H05K 1/02; H05K 1/11

(52) U.S. Cl. CPC H05K 1/0245; H05K 1/0218; H05K 1/113; H05K 1/118; H05K 2201/042; H05K 2201/09236; H05K 2201/093; H05K 2201/0939; H05K 2201/09609; H05K 2201/09618; H05K 2201/09636; H05K 2201/09754; H05K 2201/10234

(57) ABSTRACT

A circuit board designed for high-frequency and high-speed data transmission is disclosed. The circuit board features a compact layout for differential pair circuits with less elevation occupied on one end, resulting in a circuit board shaped with a narrow side and a wide side. The narrow side is adapted for electrical coupling with an ASIC substrate, while the wide side is adapted for electrical coupling with at least one Ethernet port. This design creates an extremely short-range (XSR) interface between the ASIC and the Ethernet port.

### BACKGROUND

### Technical Field

The present invention pertains to a circuit board specifically designed for high-frequency and high-speed data transmission, making it particularly suited for manufacturing connectors for data transmission. This circuit board features a funnel shape with a narrow end and a wide end. The narrow end is adapted for electrical coupling to an ASIC substrate, while the wide end is adapted for electrical coupling to at least one Ethernet port. A plurality of parallel circuit traces, with minimal spacing between them, are configured on the narrow side of the circuit board and positioned near one another.

### Description of Related Art

FIGS. 1 shows a prior art.

FIG. 1 shows that prior art US20240128665 discloses a traditional differential pair circuit 105 on a circuit board 104. The traditional differential pair circuit 105 occupies approximately a rectangular space. FIG. 1 shows a plurality of differential pair circuits 105 configured on the circuit board 104. In FIG. 1, only two sets of differential pair circuits 105 are exemplified. Each differential pair circuit 105 has parallel circuit traces 105P in the middle, with their right ends electrically coupled to corresponding rectangular metal pads 106. The left ends of these traces are electrically coupled to corresponding circular metal pads 107. The two left circular metal pads 107 are positioned on opposite sides of the parallel circuit traces 105P, which is configured along the X direction. Each differential pair circuit 105 occupies the same elevation for the left side E1 and right side E2, the left elevation E1=1,200 um and the right elevation E2=1200 um, these dimensions are calculated based on the following parameters: right rectangular metal pad 106 has a height of 300 um with a space height of 300 um between neighboring rectangular metal pads 106.

The traditional circuit patent of differential pair circuit 105, featuring a rectangular outline, limits its application in miniature uses, especially in high-frequency and high-speed data transmission applications that require shorter transmission routes.

### SUMMARY OF THE INVENTION

The present invention features a circuit layout for differential pair circuits that positions the left circular metal pads on the same side, for some embodiments, with reference to the parallel circuit traces of the differential pair circuits, results in less space occupied on the left side. Consequently, it can electrically couple to the ASIC substrate directly. This design allows the circuit board to adopt a funnel shape with a narrow side E1 and a wide side E2. The narrow side E1 is adapted for electrical coupling with an ASIC substrate, while the wide side E2 is adapted for electrical coupling with at least one Ethernet port. This invention implements an extremely short-range (XSR) interface between the ASIC and the Ethernet port.

### BRIEF DESCRIPTION OF THE DRAWINGS

FIG. 1 shows a prior art.

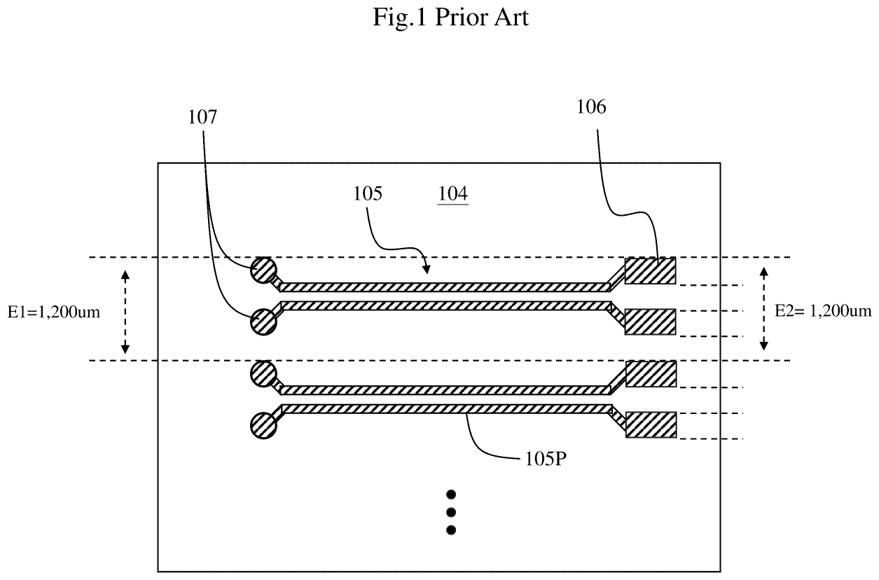

FIG. 2 shows a first layout for the circuit traces according to the present invention.

FIG. 3A˜3E show five possible layouts according to the present invention.

FIG. 4A˜4D show a second layout for the circuit traces according to the present invention.

FIG. 5 shows a third layout for the circuit traces according to the present invention.

FIG. 6 shows fourth layout for the circuit traces according to the present invention.

FIG. 7A˜7C show a fifth layout for the circuit traces according to the present invention.

FIG. 8A˜8B show a sixth layout for the circuit traces according to the present invention.

FIG. 9 shows an outline of a circuit board according to the present invention.

FIG. 10 shows a seventh layout for the circuit traces according to the present invention.

FIG. 11 shows an application for the circuit board according to the present invention.

FIG. 12 shows a dimension-referenced layout for the circuit traces according to the present invention.

FIG. 13 shows a side view of FIG. 11 according to the present invention.

FIG. 14A˜14B show embodiments for connectors according to the present invention.

FIG. 15 shows an application for the connectors according to the present invention.

FIG. 16 shows a circuit board stack for connectors according to the present invention.

FIG. 17 shows an application for the connector of FIG. 18 according to the present invention.

FIG. 18A˜18B show a first metal sprig contact for the circuit board according to the present invention.

FIG. 19A˜19B show a second metal sprig contacts for the circuit board according to the present invention.

FIG. 20 shows a third embodiment for a connector according to the present invention.

FIG. 21A˜21B show an eighth layout for the circuit traces according to the present invention.

FIG. 22 shows a dimension-referenced layout for the circuit traces according to the present invention.

FIG. 23 shows a ninth layout for the circuit traces according to the present invention.

FIG. 24 shows a tenth layout for the circuit traces according to the present invention.

FIG. 25 shows a sectional view of FIG. 22 according the present invention.

FIG. 26 shows a fourth embodiment for a connector according to the present invention.

FIG. 27A˜27B show an eleventh layout for the circuit traces according to the present invention.

FIG. 28A˜28B shows a first design for the hole or metal via with reference to a corresponding clearance on the ground plane according to the present invention.

FIG. 29A˜29B shows a second design for the hole or metal via with reference to a corresponding clearance on the ground plane according to the present invention.

FIG. 30A˜30B shows a third design for the hole or metal via with reference to a corresponding clearance on the ground plane according to the present invention.

FIG. 31A˜31B shows a fourth design for the hole or metal via with reference to a corresponding clearance on the ground plane according to the present invention.

FIG. 32A˜32B shows a fifth design for the hole or metal via with reference to a corresponding clearance on the ground plane according to the present invention.

FIG. 33A˜33B shows a sixth design for the hole or metal via with reference to a corresponding clearance on the ground plane according to the present invention.

### DETAILED DESCRIPTION OF THE INVENTION

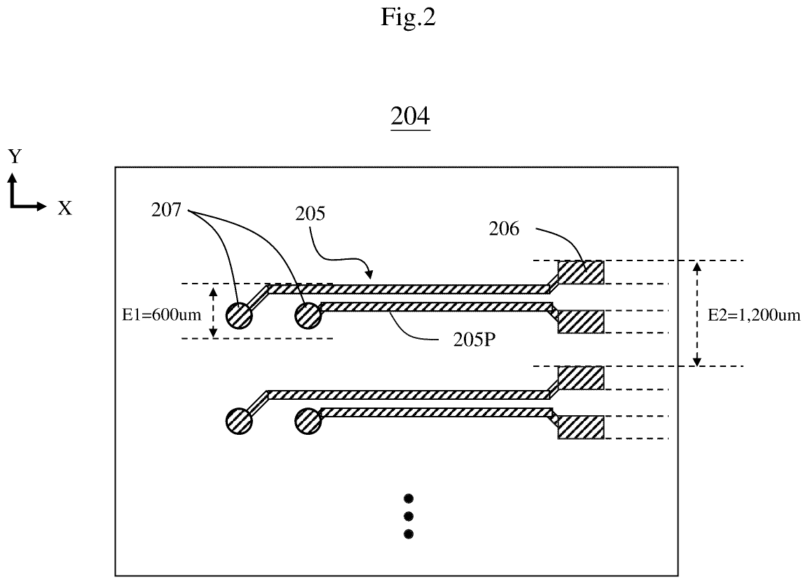

FIG. 2 shows a first layout for the circuit traces according to the present invention.

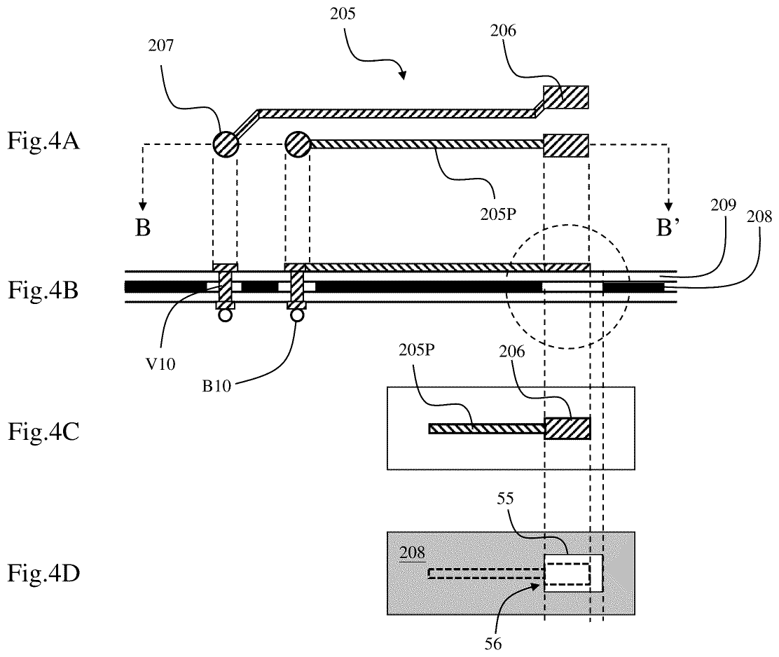

FIG. 4 shows a plurality of differential pair circuits 205 configured on a circuit board 204. The left circular metal pads 207 of the differential pair circuit 205 is configured on the same side of the parallel circuit traces 205P and aligned along the X direction. Accordingly, the left elevation E1 can be reduced to half of the right elevation E2. The left elevation E1 measures approximately 600 μm, which is half the right elevation E2 of 1,200 μm. The dimension calculations are based on the following parameters: the circuit trace has a height, or trace width, of 100 μm in the Y direction, the space between circuit traces 205 is 100 μm in height, the circular metal pad 207 has a diameter of 300 μm, the rectangular metal pad 206 has a height of 300 μm, and the space between the rectangular metal pads 206 is 300 um. However, these dimensions are merely examples; smaller dimensions may become feasible as technology advances.

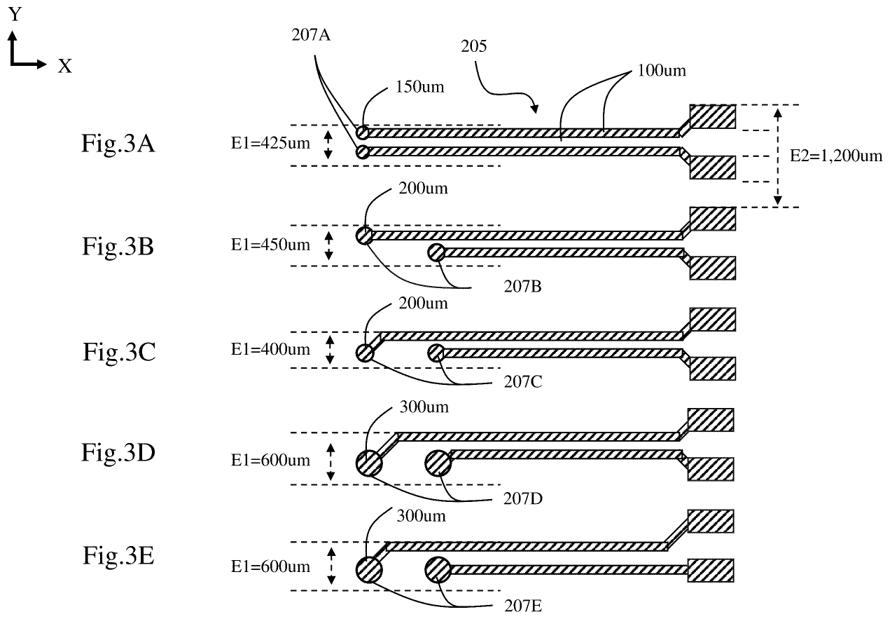

FIG. 3A˜3E show five possible layouts according to the present invention.

FIG. 3A shows that the two circular metal pads 207A of the differential pair circuit 205 are aligned in the Y direction. This is based on the following parameters:
the circular pad has a diameter of 150 um, and the circuit trace has a height of 100 um. The left elevation E1 of the differential pair circuit occupies approximately 425 um, which is 35.4% of the right elevation E2 of the differential pair circuit that occupies 1,200 um.

FIG. 3B shows that the two circular metal pads 207B of the differential pair circuit 205 are staggered to avoid a circuit short when the circular metal pads 207B has a larger size. This is based on the following parameters: the circular pad has a diameter of 200 um, while either the circuit trace or the space width has a height of 100 um. The left elevation E1 of the differential pair circuit 205 occupies approximately 450 um, which is 37.5% of the right elevation E2 of the differential pair circuit 205 that occupies 1,200 um.

FIG. 3C shows that the two circular metal pads 207C of the differential pair circuit 205 are aligned in the X direction. The top circuit trace electrically couples with the corresponding circular metal pad 207C with a turn connection. This is based on the following parameters: the circular metal pad 207C has a diameter of 200 um, while either the circuit trace or the space width has a height of 100 um. The left elevation E1 of the differential pair circuit occupies approximately 400 um, which is one-third of the right elevation E2 of the differential pair circuit that occupies 1,200 um.

FIG. 3D shows that the two circular metal pads 207D of the differential pair circuit 205 are aligned in the X direction with larger metal pads. Each circuit trace electrically couples with a corresponding circular metal pad 207D with a turn connection. This is based on the following parameters: the circular pad has a diameter of 300 um, while either the circuit trace or the space width has a height of 100 um. The left elevation E1 of the differential pair circuit 205 occupies approximately 600 um, which is one half of the right elevation E2 of the differential pair circuit 205 that occupies 1,200 um.

FIG. 3E shows that the two circular metal pads 207E of the differential pair circuit 205 are aligned in the X direction., with the top circuit trace electrical coupling to the corresponding circular metal pad 207E with a turn connection while with the bottom circuit trace to directly electrically couple to the corresponding circular metal pad 207E without a turn connection. This is based on the following parameters: the circular metal pad 207E has a diameter of 300 um, while either the circuit trace or the space width has a height of 100 um. The left elevation E1 of the differential pair circuit 205 occupies approximately 600 um, which is one half of the right elevation E2 of the differential pair circuit 205 that occupies 1,200 um.

FIG. 4A˜4D show a second layout for the circuit traces according to the present invention.

FIG. 4A shows a top view of the layout, a differential pair circuit 205 having parallel circuit traces 205P, circular metal pad 207, and rectangular metal pad 206.

FIG. 4B shows a sectional view according to line BB′ of FIG. 4A. FIG. 4B shows a ground plane 208 is configured beneath the circuit traces 205 with an insulation layer 209 placed between them. A plurality of circular metal pads 207 are configured on the left side of the differential pair circuits 205. A plurality of metal vias V10 are configured to pass through the circuit board, extending from the top to the bottom side of the circuit board. The top end of each metal via V10 is electrically coupled to a corresponding circular metal pad 207. A plurality of metal balls B10 are configured on the bottom side of the circuit board. Each metal ball B10 is electrically coupled with a corresponding vertical metal via V10.

FIG. 4C shows a top view of the rectangular metal pad 206 and an incoming circuit trace 205P.

FIG. 4D shows that a clearance 55 is formed on the ground plane 208. larger than the rectangular metal pad 206. The clearance 55 has a size greater than the rectangular metal pad 206; the clearance 55 overlaps the rectangular metal pad 206; and the clearance 55 has a flat boundary 56 overlapping a junction between the rectangular metal pad 206 and the incoming circuit trace 205P.

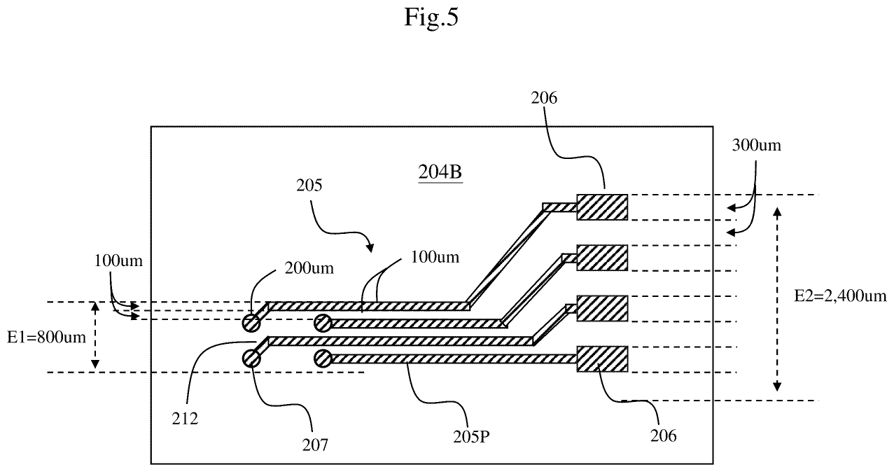

FIG. 5 shows a third layout for the circuit traces according to the present invention.

FIG. 5 shows a plurality of differential pair circuits 205 configured on a circuit board 204B. The plurality of differential pair circuits 205 has parallel circuit traces 205P horizontally configured as an example. The plurality of parallel circuit traces 205P are compactly configured in the Y direction according to the present invention. The left elevation E1, occupied by the parallel circuit traces 205P, measuring approximately E1=800 um, which is one-third of the right elevation E2 occupied by the rectangular meta pads 206, where E2=2,400 um. The dimension calculations are based on the following parameters: each circular metal pad 207 has 200 um in diameter, each circuit trace of the parallel circuit traces 205P has a height of 100 um, among the parallel portion, each space between neighboring circuit traces is 100 um, each rectangular metal pad 206 has a height of 300 um high, and each space between neighboring rectangular metal pads 206 has a height of 300 um.

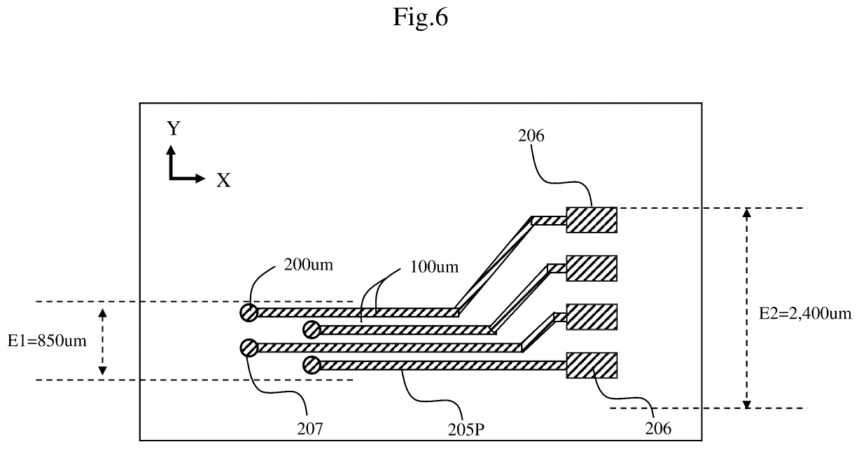

FIG. 6 shows fourth layout for the circuit traces according to the present invention.

FIG. 6 shows each parallel circuit traces 205P electrically couples with a corresponding circular metal pad 207 with a direct connection. With this configuration, the left elevation E1 occupied by the parallel circuit traces 205P is approximately 850 um, which is 35.4% of the right elevation E2 occupied by the rectangular meta pads 206, where E2=2,400 um.

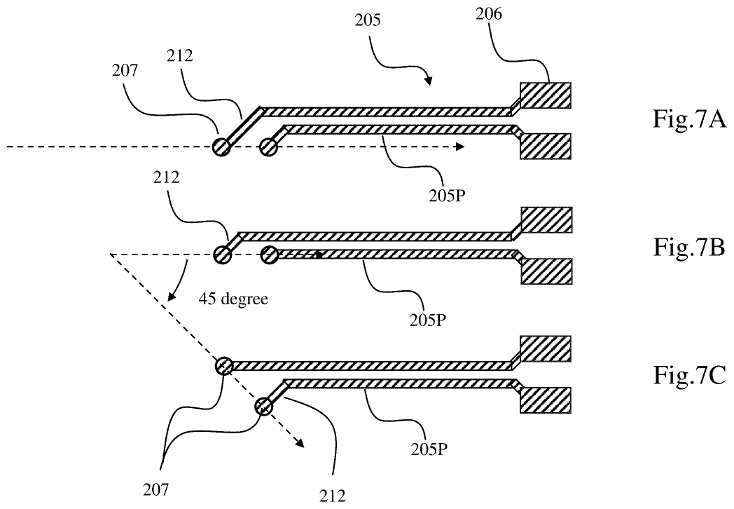

FIG. 7A˜7C show a fifth layout for the circuit traces according to the present invention.

FIG. 7A shows that the two circular metal pads 207 of a differential pair circuit 205 are aligned along the horizontal direction, or the X direction; while the two parallel circuit traces 205P electrically couple with the circular metal pads 207 with a turn connection 212.

FIG. 7B shows that the two circular metal pads 207 of a differential pair circuit 205 are aligned along the horizontal direction, or the X direction. The top circuit trace electrically couples with the left circular metal pad 207 with a turn connection 212, and the bottom circuit trace electrically couples with the circular metal pad 207 with a direct connection.

FIG. 7C shows that the two circular metal pads 207 of a differential pair circuit 205 are aligned along a line at 45 degrees with respect to the horizontal direction; while the top circuit trace electrically couples with the corresponding circular metal pad 207 with a direct connection, and the bottom circuit trace electrically couples with the corresponding circular metal pad 207 with a turn connection 212.

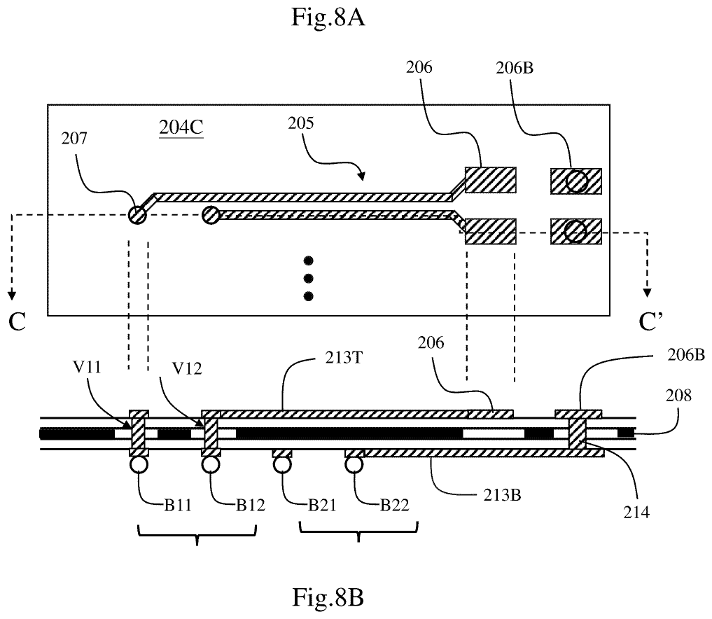

FIG. 8A˜8B show a sixth layout for the circuit traces according to the present invention.

FIG. 8A shows a top view of a plurality of differential pair circuits configured on the circuit board 204C. A plurality of first rectangular metal pads 206 and a plurality of second rectangular metal pads 206B are configured on the right side of the circuit board 204C. The first rectangular metal pads 206 are extensions of a first circuit layer 213T configured on the top side of the circuit board 204C; while The second rectangular metal pads 206B are extensions of a second circuit layer 213B configured on the bottom side of the circuit board 204C.

FIG. 8B shows a sectional view along line CC′ of FIG. 8A.

FIG. 8B shows that the second rectangular metal pads 206B are extensions of a second circuit layer 213B which is configured on the bottom side of the circuit board 204C. The second rectangular metal pads 206B are electrically coupled with the second circuit layer 213B through a vertical metal via 214. A ground plane 208 is positioned between the two circuit layers 213T, 213B.

A plurality of first metal balls B11, B12 are configured on a bottom side of the circuit board 204C. Each first metal ball B11, B12 electrically couples with a corresponding circuit trace of the first circuit layer 213T. A plurality of second metal balls B21, B22 are configured on the bottom side of the circuit board 204C. Each second metal ball B21, B22 electrically couples with a corresponding circuit trace of the second circuit layer 213B. A plurality of metal vias V11, V12 are configured on the left side of the circuit board 204C. Each metal via V11, V12 electrically couples with a corresponding circular metal pad 207 on top of the metal via V11, V12. The metal vias V11, V12 vertically configured and each electrically couples with a corresponding metal pad 207 of the first circuit layer 213T.

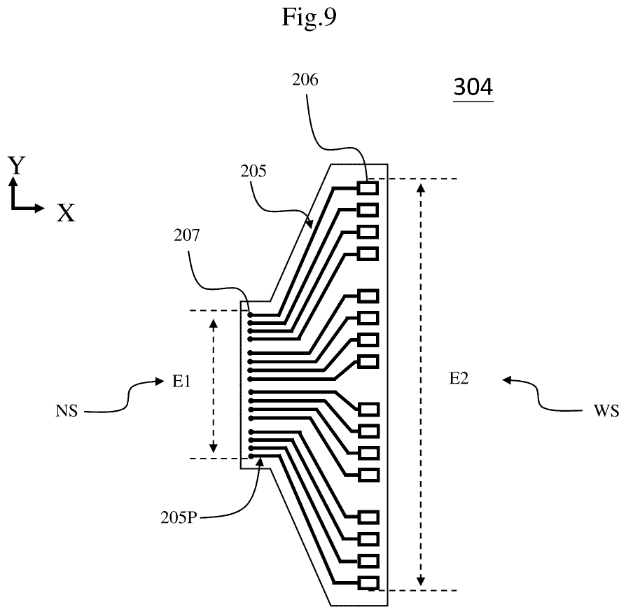

FIG. 9 shows an outline of a circuit board according to the present invention.

FIG. 9 shows that the circuit board 304 is funnel-shaped with a narrow side (NS) on the left and a wide side (WS) on the right. A plurality of differential pair circuits 205 configured on the circuit board 304. A plurality of circular metal pads 207 are configured on the left side of the circuit board 304, and a plurality of rectangular metal pads 206 are configured on the right side of the circuit board 304. Each circuit trace of the differential pair circuit 205 has a left end electrically coupled with a corresponding circular metal pad 207, and a right end electrically coupled with a corresponding rectangular metal pad 206.

A plurality of metal vias V11, V12 (FIG. 8A˜8B) configured on a left side of the circuit board 304. Each metal via V11, V12 electrically couples with a corresponding circular metal pad 207 on a top of each metal via V11, V12. Each parallel circuit trace 205P has a left end electrically coupled to a corresponding metal via V11, V12 through a corresponding metal pad 207; the parallel circuit traces 205P, extending horizontally or in an X direction, configured on the left side of the circuit board 304. A plurality of rectangular metal pads 206 are aligned vertically (or in the Y direction) and configured on the right side of the circuit board 304. Each parallel circuit trace 205P has a right end electrically coupled with a corresponding rectangular metal pad 206.

The parallel circuit traces 205P occupies a left elevation E1 vertically (or in the Y direction), on the narrow side (NS) of the circuit board 304. The plurality of right metal pads 206 occupies a right elevation E2 vertically (or in the Y direction) on the wide side (WS) of the circuit board 304. The left elevation E1 is smaller than the right elevation E2 due to the rearrangement of the circular metal pads 207 according to the present invention.

The narrow side (NS) with the plurality of metal vias V11, V12 is adapted to electrically couple with one of interposer, ASIC substrate, CPU substrate, IC substrate, and circuit board, while the wide side (WS) with the plurality of rectangular metal pads 206 is adapted to electrically couple to at least one high speed I/O such as ethernet port.

FIG. 9 shows that the upper half of parallel circuit traces 205P have their right ends staggered and shifted to the right in sequence, while the lower half of the parallel circuit traces 205P have their right ends staggered and shifted to the left in sequence.

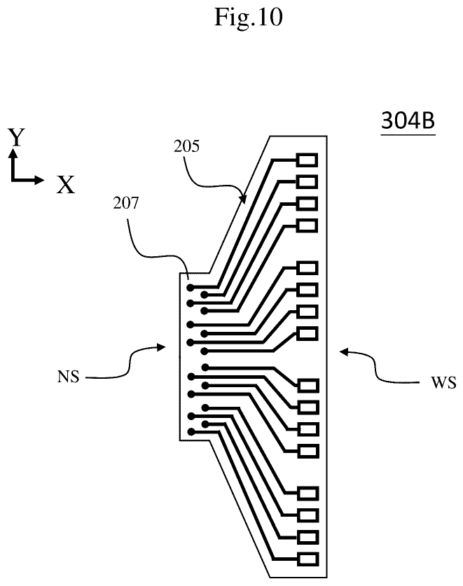

FIG. 10 shows a seventh layout for the circuit traces according to the present invention.

FIG. 10 shows that the circular metal pads 207 are staggered to prevent short-circuiting between them when the circular metal pads 207 are larger, while the other portions are similar to those in the previous figure.

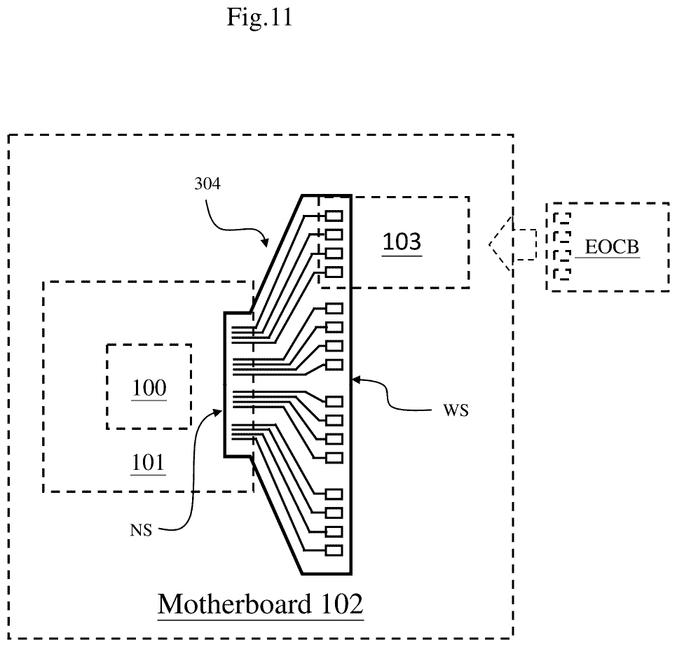

FIG. 11 shows an application for the circuit board according to the present invention.

FIG. 11 shows that the left side NS of the circuit board 304 is adapted for electrically coupling with an ASIC substrate, while the right side WS is adapted for electrically coupling with at least one Ethernet port 103.

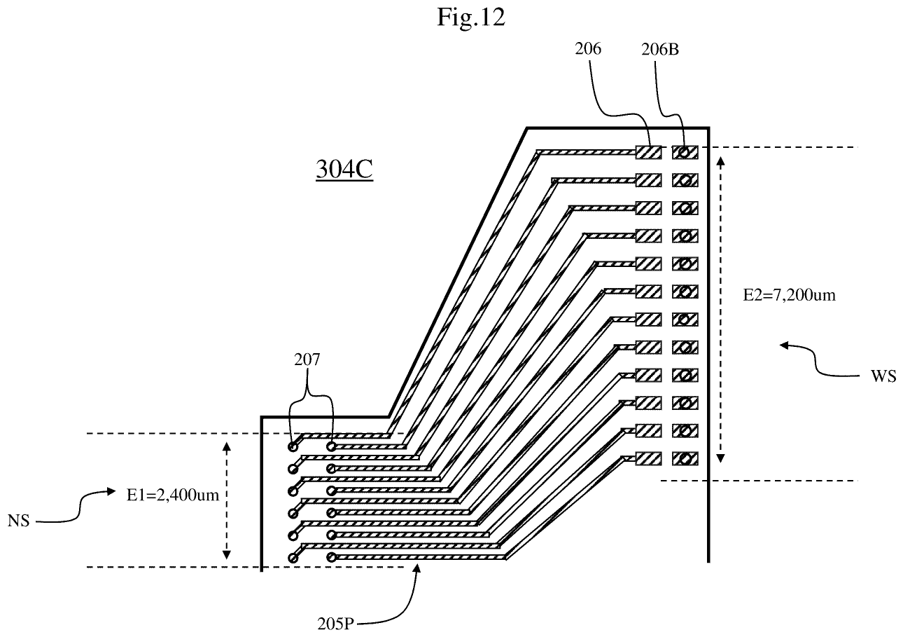

FIG. 12 shows a dimension-referenced layout for the circuit traces according to the present invention.

FIG. 12 shows only the upper portion of the circuit board 304C, where a plurality of parallel circuit traces 205P are configured compactly and occupy a left elevation of E1=2,400 um on the narrow side (NS), and the plurality of rectangular metal pads 206, 206B occupies a right elevation of E2=7,200 um on the wide side (WS). The left elevation E1 is one-third of the right elevation E2. This is based on the following parameters: each left circular metal pad 207 has a diameter of 200 um, each trace width of the parallel circuit traces has a height of 100 um, and each space width among the parallel circuit traces has a height of 100 um, and each rectangular metal pad 206 has a height of 300 um and each space between the neighboring rectangular metal pads 226 has a height of 300 um.

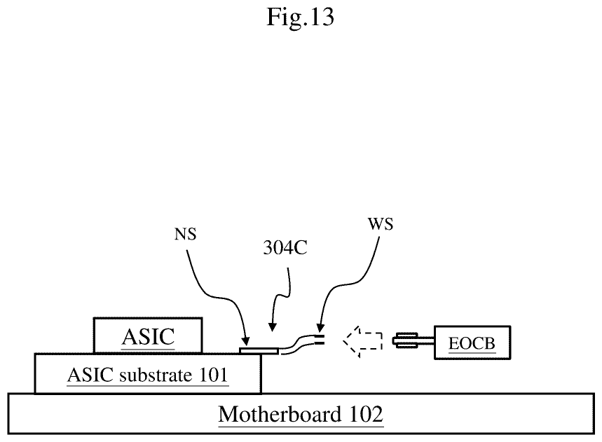

FIG. 13 shows a side view of FIG. 11 according to the present invention.

FIG. 13 shows that the narrow side (NS) of the circuit board 304C is directly configured on the ASIC substrate 101, while the wide side (WS) of the circuit board 304C is configured to electrically couple with at least one Ethernet port 103 that provides a connection for the EOCB.

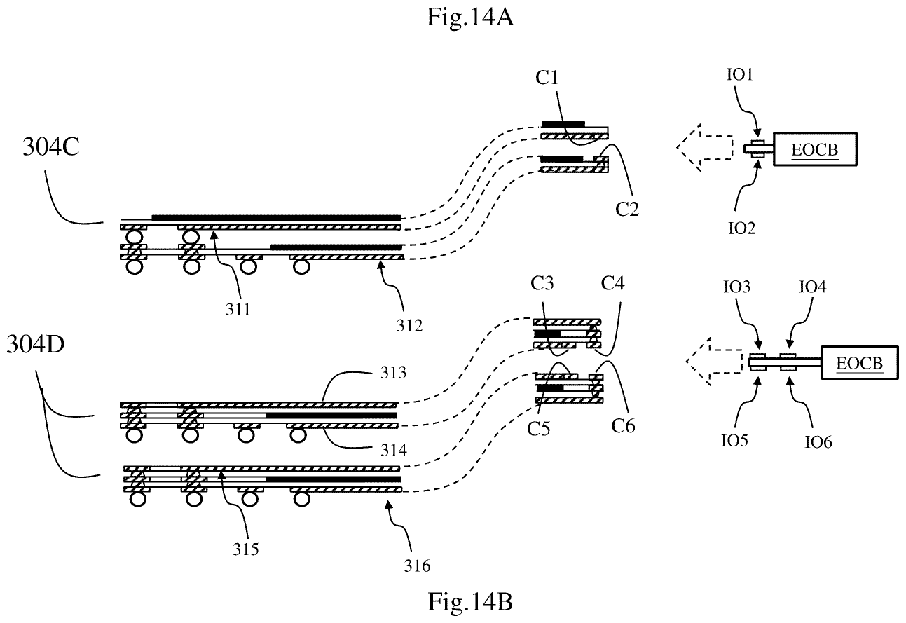

FIG. 14A˜14B show embodiments for connectors according to the present invention.

FIG. 14A shows a first embodiment for a connector according to the present invention. FIG. 14A shows that two circuit boards 304C are stacked, with their right sides being bendable. These bendable right sides are suitable for forming a female connector that is adapted for coupling with a male connector. There first circuit board 304C has a first signal circuit layer 311, and the second circuit board 304C has a second signal circuit layer 312. The female connector is composed of a top array of metal contacts C1, which are metal contacts of the first signal circuit layer 311, and a bottom array of metal contacts C2, which are metal contacts of the second signal circuit layer 312. The female connector is designed to accept a male connector. The EOCB has a male connector composed of a first array of metal contacts IO1 on the top side, and a second array of metal contacts IO2 on the bottom side.

FIG. 14B shows a second embodiment for a connector according to the present invention.

FIG. 14B shows two independent circuit boards 304D. The first circuit board 304D has two signal circuit layers 313, 314. The second circuit board 304D has two signal circuit layers 315, 316. Their bendable right sides are suitable for forming a female connector which is designed to accept a male connector. A female connector is composed of two top arrays of metal contacts C3, C4, which are extension contacts of the two signal circuit layers 313, 314; and two bottom arrays of metal contacts C5, C6, which are extension contacts of the two signal circuit layers 315, 316. This configuration is suitable for accept a male connector with double array of metal contacts on both sides. An EOCB with a male connector composed of a first double array of metal contacts IO3, IO4 on the top side, and a second double array of metal contacts IO5, IO6 on the bottom side.

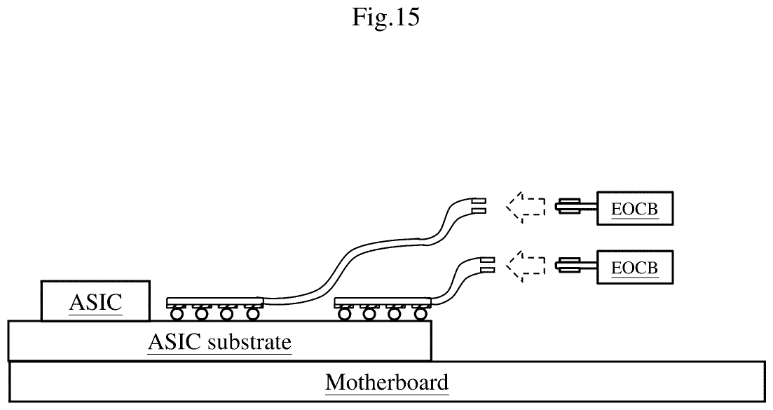

FIG. 15 shows an application for the connectors according to the present invention.

FIG. 15 shows that two connectors are configured on the top of ASIC substrate that is designed to accept double male connectors.

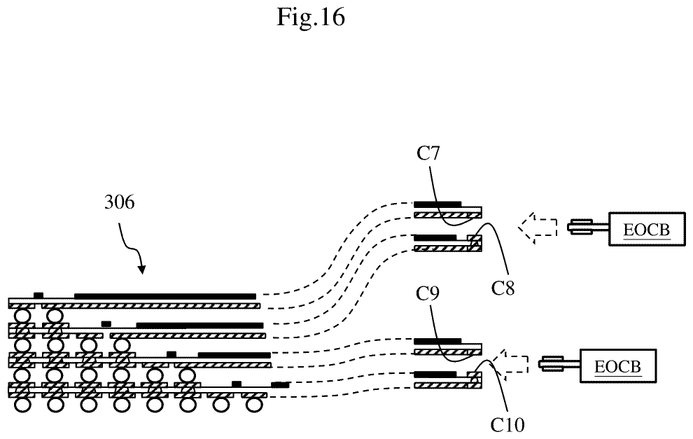

FIG. 16 shows a circuit board stack for connectors according to the present invention.

FIG. 16 shows that the circuit board 306 has four signal circuit layers and is suitable for forming two connectors. The top female connector has opposing arrays of metal contacts C7, C8 that are adapted to accept a male connector. The bottom female connector has opposite arrays of metal contacts C9, C10 that are adapted to accept a male connector.

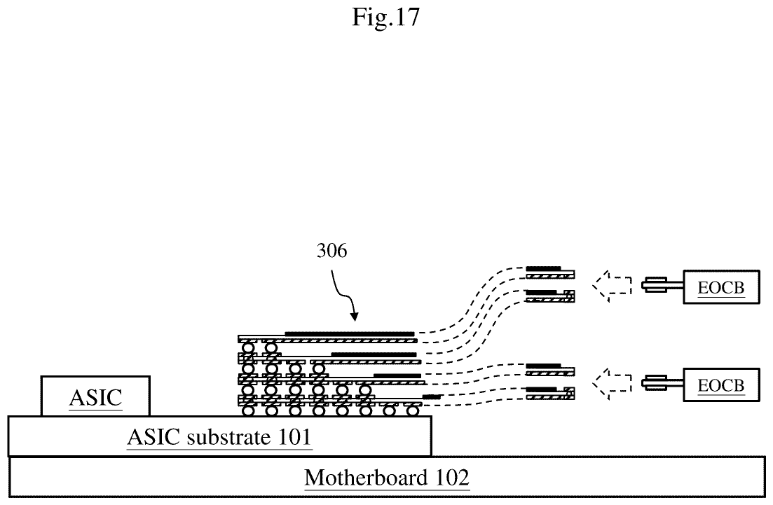

FIG. 17 shows an application for the connector of FIG. 16 according to the present invention.

FIG. 17 shows that the circuit board stack 306 is suitable for configuration on the ASIC substrate 101 and can accommodate two male connectors.

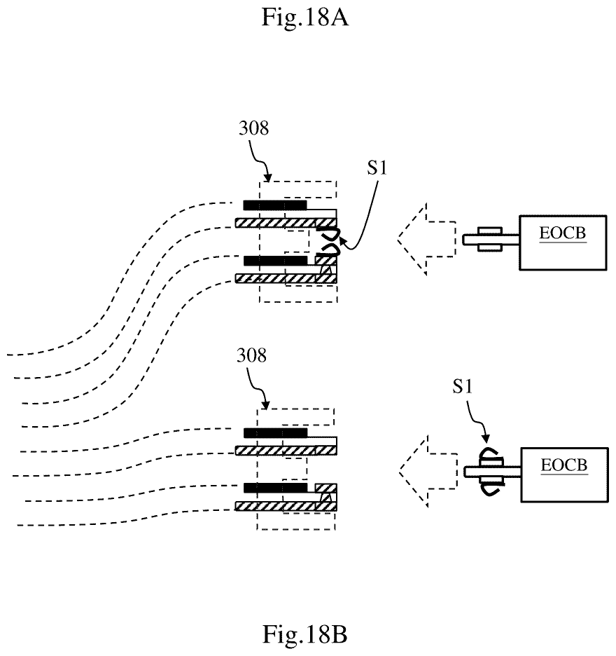

FIG. 18A˜18B show a first metal sprig contact for the circuit board according to the present invention.

FIG. 18A shows that a plurality of first metal springs S1 are designed into the connector. Each first metal spring S1 is shaped like a lowercase sigma and has a flat portion for mounting on the surface of a corresponding metal contact. It also has a V-shaped portion that points away from the surface of the corresponding metal contact, functioning as an extended electrical contact. A bracket 308 frames the flexible ends of the circuit boards, transforming them into a female connector. This configuration ensures that the flexible ends are securely held, making them suitable for connecting with a corresponding male connector.

FIG. 18B shows that the first metal springs S1 can be applied on a male connector such as an EOCB. Each first metal spring S1 is shaped like a lowercase sigma and has a flat portion for mounting on the surface of a corresponding metal pad of the EOCB. It also has a V-shaped portion that points away from the surface of the corresponding metal contact, functioning as an extended electrical contact.

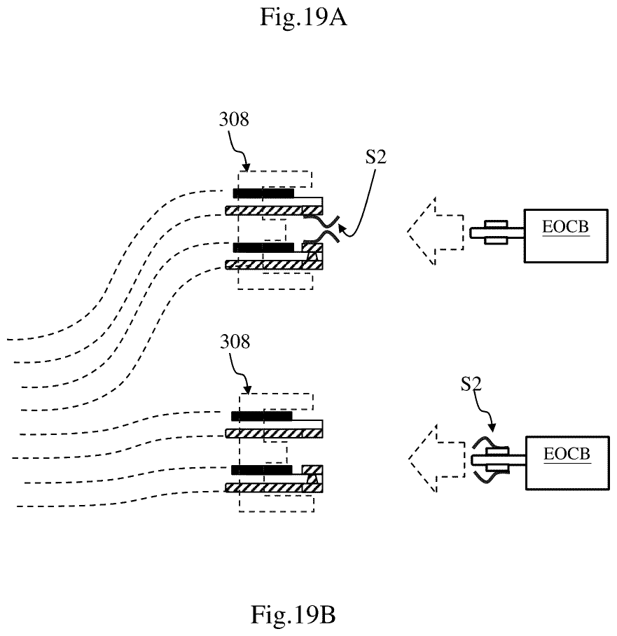

FIG. 19A˜19B show a second metal sprig contacts for the circuit board according to the present invention.

FIG. 19A shows that a plurality of second metal springs S2 are designed in the connector. The second metal spring is shaped like a teaspoon. Each second metal spring S2 has a flat portion for mounting on a surface of a corresponding metal contact. It also has a V shaped portion that points away from the surface of the corresponding metal contact, functioning as an extended electrical contact for the connector of EOCB.

FIG. 19B shows that the second metal springs S2 can also be applied on a male connector such as an EOCB. Each second metal spring S2 is shaped like a teaspoon. Each second spring S2 has a flat portion for mounting on the surface of a corresponding metal pad of the EOCB. It also has a V-shaped portion that points away from the surface of the corresponding metal contact, functioning as an extended electrical contact.

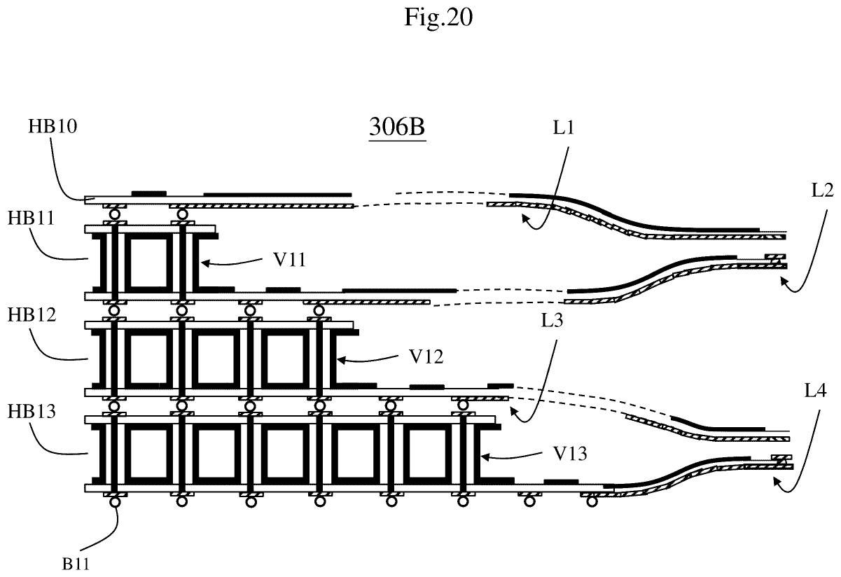

FIG. 20 shows a third embodiment for a connector according to the present invention.

FIG. 20 show a circuit board stack 306B made of hardboards HB10, HB11, HB12, HB13, where the top circuit board HB10 can be either hardboard or flexible board. All hardboards are made bendable at their right ends by removing most portion of the substrate, leaving only a few circuit layers.

The hardboard has a bendable right end, created by partially removing the top portion of the hardboard while retaining at least the bottom circuit layer to ensure flexibility.

FIG. 20 shows that four signal circuit layers L1, L2, L3, and L4 are configured in the circuit boards stack 306B. A plurality of coaxial metal vias (V11, V12, V13) are configured on the left side to electrically couple the upper signal circuit layers to corresponding bottom metal balls B11. The four bendable right ends form two female connectors that resemble either FIG. 18 or FIG. 19.

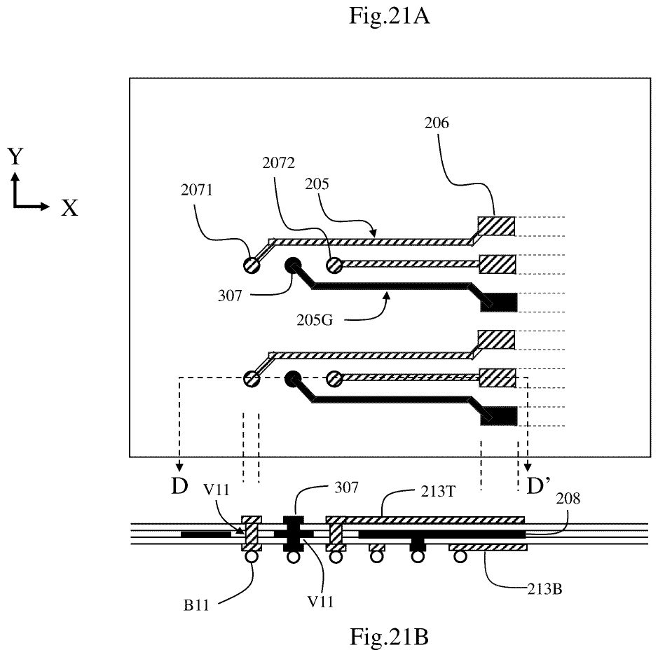

FIG. 21A˜21B show an eighth layout for the circuit traces according to the present invention.

FIG. 21A shows a top view of a modified layout for the circuit traces. A ground trace 205G is added to the differential pair circuit. The ground trace 205G is configured between neighboring differential pair circuits to help prevent crosstalk between them. A ground metal pad 307 is configured between two circular metal pads 2071, 2072.

FIG. 21B shows a sectional view along line DD′ of FIG. 21A.

A top circuit layer 213T configured on the top of the circuit board, a bottom circuit layer 213 B configured on the bottom of the circuit board, and a ground plane 208 configured in between. The ground trace 205G electrically couples to the ground plane 208 through metal pad 307 and a corresponding metal via 11. A plurality of vertical metal vias V11 electrically couples with the first circuit layer 213T to corresponding bottom metal balls B11.

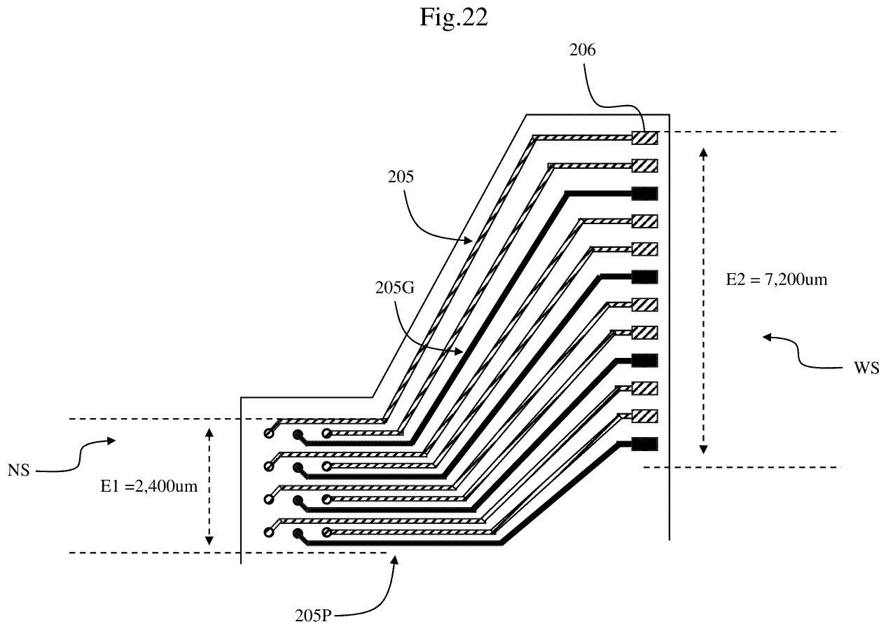

FIG. 22 shows a dimension-referenced layout for the circuit traces according to the present invention.

FIG. 22 shows only the upper portion of the circuit board. A ground trace 205G is added to each differential pair circuit 205. The ground trace 205G is situated between the adjacent differential pair circuits. A plurality of parallel circuit traces 205P are configured compactly and occupy a left elevation of E1=2,400 um on the narrow side (NS), while the plurality of rectangular metal pads 206, 206B occupies a right elevation of E2=7,200 um on the wide side (WS). The left elevation E1 is one-third of the right elevation E2.

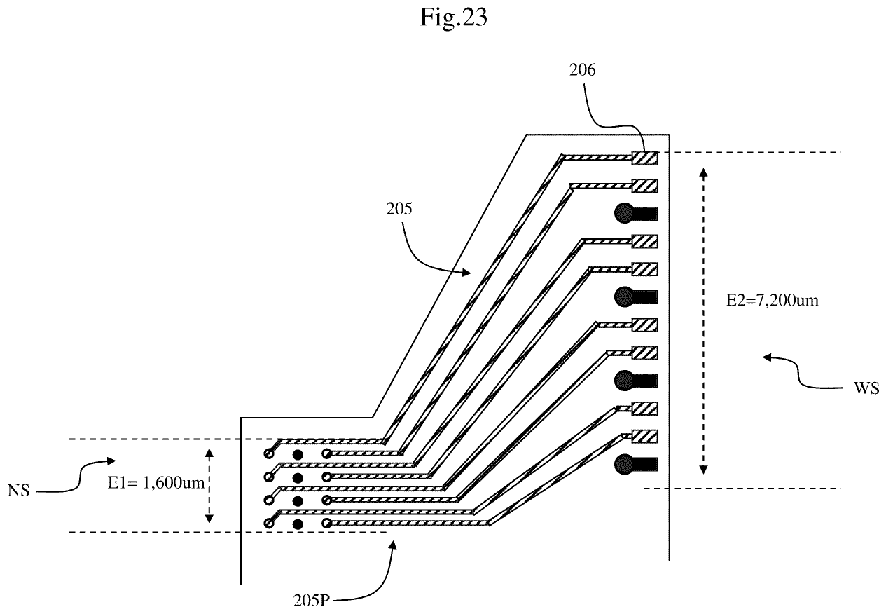

FIG. 23 shows a ninth layout for the circuit traces according to the present invention.

FIG. 23 illustrates that the ground traces 205G of FIG. 22 are removed, resulting in a more compact arrangement of the parallel circuit traces 205P.

FIG. 23 shows that a plurality of parallel circuit traces 205P are configured compactly and occupy a left elevation of E1=1,600 um on the narrow side (NS), and the plurality of rectangular metal pads 206 occupies a right elevation of E2=7,200 um on the wide side (WS). The left elevation E1 is one-third

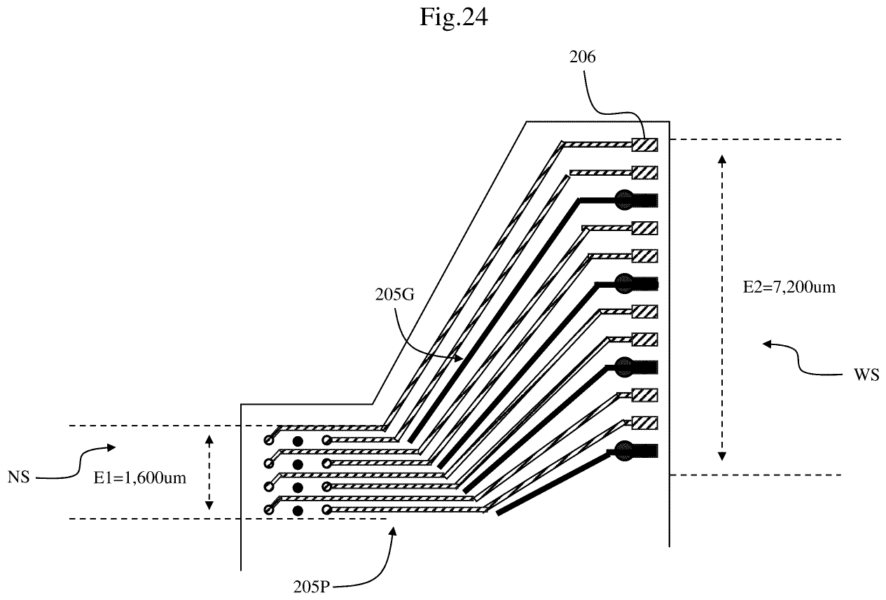

FIG. 24 shows a tenth layout for the circuit traces according to the present invention.

FIG. 24 shows that only the ground traces 205G among the parallel circuit traces 205P from FIG. 22 are removed, while the remaining ground traces stay unchanged.

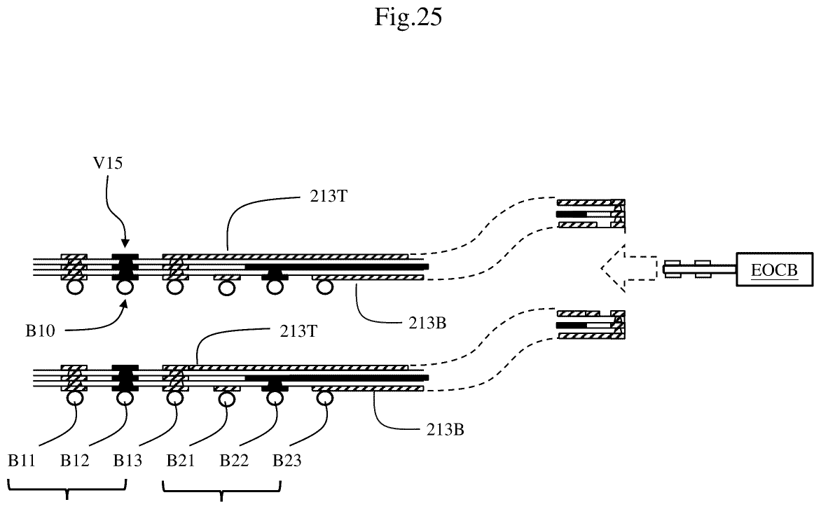

FIG. 25 shows a sectional view of FIG. 22 according the present invention.

FIG. 25 shows a vertical metal via V15 electrically couples with a ground trace 205G (FIG. 22 ) on the top surface to a bottom metal ball B10 of the circuit board. The metal balls B11, B12, B13 are metal contacts electrically coupled with the first circuit layer 213T, and the metal balls B21, B22, B23 are metal contacts electrically coupled with the second circuit layer 213B.

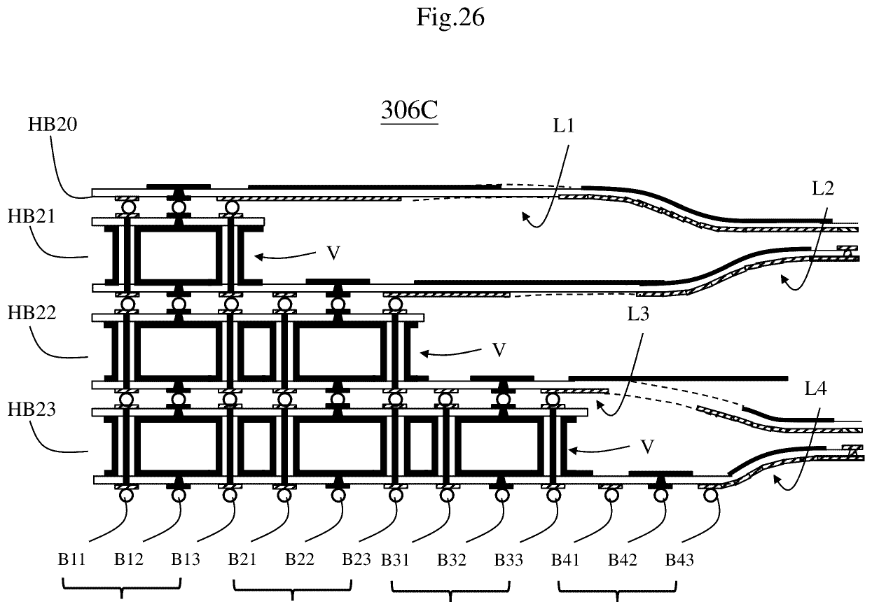

FIG. 26 shows a fourth embodiment for a connector according to the present invention.

FIG. 26 shows that a circuit board stack 306C having four circuit layer L1, L2, L3, L4. A plurality of vertical coaxial metal vias V are configured on the left side of the circuit bord stack 306C. Each vertical coaxial metal vias V electrically couples a corresponding circuit trace of the circuit layers to a corresponding bottom metal balls B11, B12, B13, B21, B22, B23. The bottom metal balls B11, B12, B13, electrically couple with the first circuit layer L1, the bottom metal balls B21, B22, B23 electrically couple with the second circuit layer L2; the bottom metal balls B31, B32, B33, electrically couple with the third circuit layer L3, and the bottom metal balls B41, B42, B43 electrically couple with the fourth circuit layer L4.

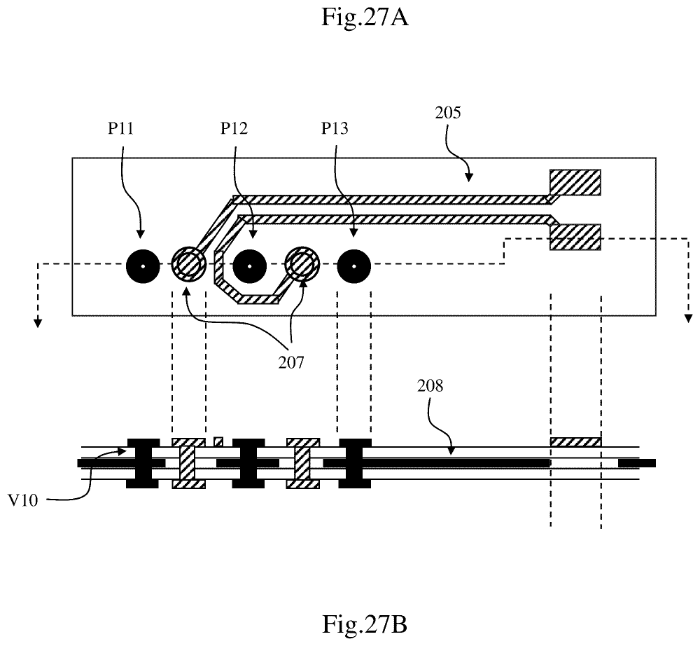

FIG. 27A˜27B show an eleventh layout for the circuit traces according to the present invention.

FIG. 27A shows three ground pads P11, P12, P13 aligned and alternating with the two circular metal pads 207 of a corresponding differential pair circuit 205. The lower circuit trace 205 has its path encircling the ground pad P12, with the longer trace compensating signal skew.

FIG. 27B shows that each ground pad P11, P12, P13 electrically couples to the ground plane 208 through a corresponding vertical metal via V10. The ground pads P11, P12, P13 and their corresponding metal vias V10 help prevent crosstalk during signal transmission.

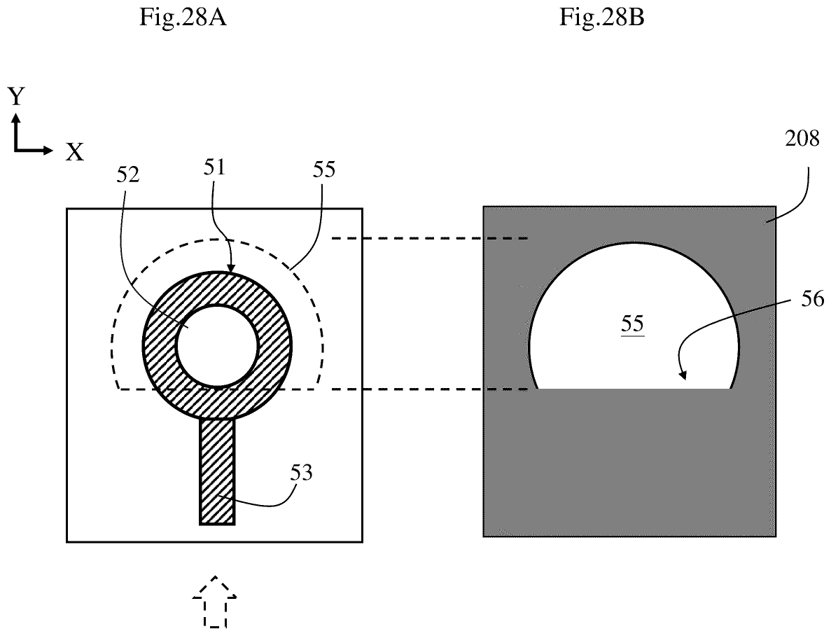

FIG. 28A˜28B shows a first design for the hole or via with reference to a corresponding clearance on the ground plane according to the present invention.

FIG. 28A shows a circular metal pad 51, a plated through hole or a metal via 52, and an incoming circuit 53 connecting to the circular metal pad 51.

FIG. 28B shows a ground plane 208 configurated below the circular metal pad 51, in the Z direction, with an insulation layer in between. A clearance 55 is configured on the ground plane 208. The clearance 55 has a size greater than the plated through hole or a metal via 52; the clearance 55 overlaps the plated through hole or a metal via 52; and the clearance 55 has a flat boundary 56, that is tangent to but does not contacting a rim of the plated through hole or the metal via 52. The flat boundary 56 is normal to the corresponding incoming circuit trace 53.

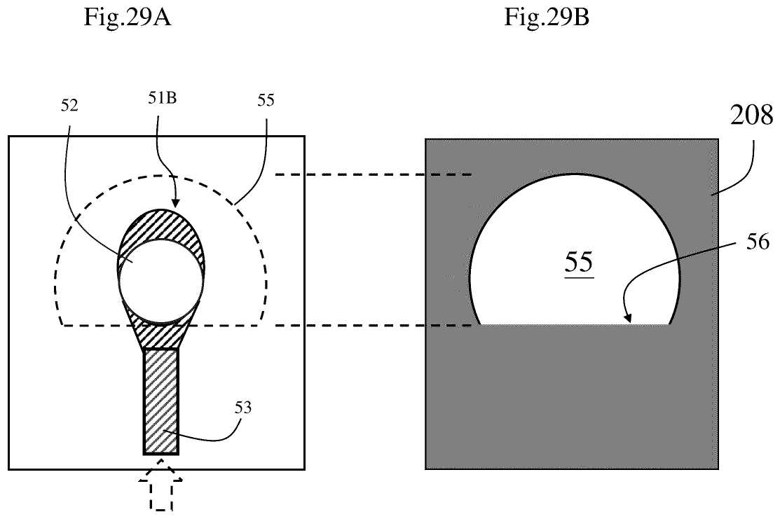

FIG. 29A˜29B shows a second design for the hole or via with reference to a corresponding clearance on the ground plane according to the present invention.

FIG. 29A shows an oval metal pad or a teardrop metal pad 51B, a plated through hole or a metal via 52, and an incoming circuit 53 connecting to the teardrop metal pad 51B. FIG. 29B shows a ground plane 208 configurated below the circular metal pad 51, in the Z direction, with an insulation layer in between. A clearance 55 is configured on the ground plane 208. The clearance 55 has a size greater than the plated through hole or a metal via 52; the clearance 55 overlaps the plated through hole or a metal via 52; and the clearance 55 has a flat boundary 56, that is tangent to but does not contacting a rim of the plated through hole or the metal via 52. The flat boundary 56 is normal to the corresponding incoming circuit trace 53.

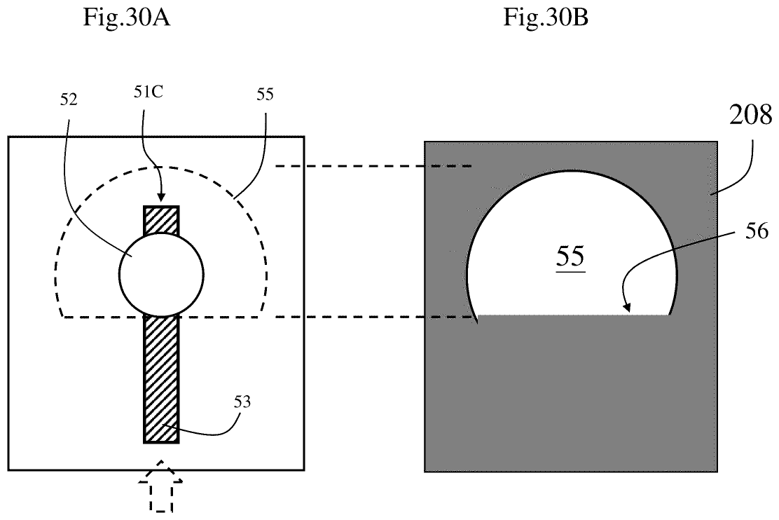

FIG. 30A˜30B shows a third design for the hole or via with reference to a corresponding clearance on the ground plane according to the present invention.

FIG. 30A shows a blade metal pad 51C, a plated through hole or a metal via 52, and an incoming circuit 53 connecting to the plated through hole or a metal via 52. The blade metal pad 51C is configured opposite or at 180 degrees to the incoming circuit trace 53.

FIG. 30B shows a ground plane 208 configurated below the circular metal pad 51, in the Z direction, with an insulation layer in between. A clearance 55 is configured on the ground plane 208. The clearance 55 has a size greater than the plated through hole or a metal via 52; the clearance 55 overlaps the plated through hole or a metal via 52; and the clearance 55 has a flat boundary 56, that is tangent to but does not contacting a rim of the plated through hole or the metal via 52. The flat boundary 56 is normal to the corresponding incoming circuit trace 53.

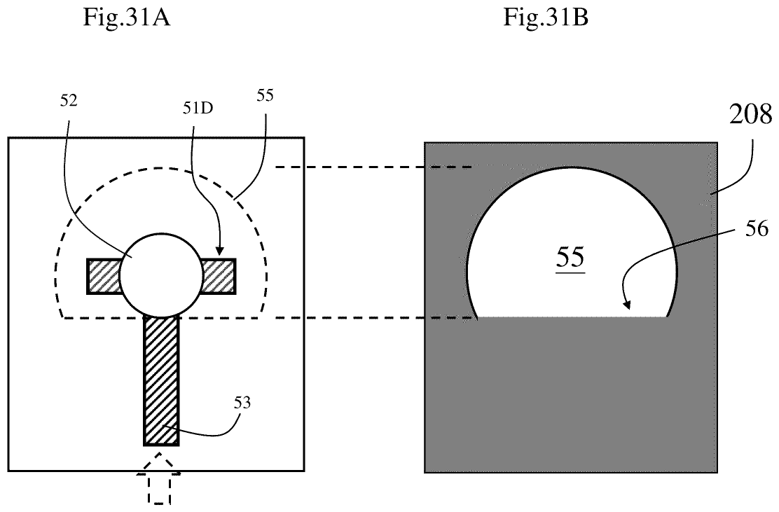

FIG. 31A˜31B shows a fourth design for the hole or via with reference to a corresponding clearance on the ground plane according to the present invention.

FIG. 31A shows two blade metal pad 51D, a plated through hole or a metal via 52, and an incoming circuit 53 connecting to the plated through hole or a metal via 52. The two blade metal pads 51D, are configured at 90 degrees to the incoming circuit trace 53.

FIG. 31B shows a ground plane 208 configurated below the circular metal pad 51, in the Z direction, with an insulation layer in between. A clearance 55 is configured on the ground plane 208. The clearance 55 has a size greater than the plated through hole or a metal via 52; the clearance 55 overlaps the plated through hole or a metal via 52; and the clearance 55 has a flat boundary 56, that is tangent to but does not contacting a rim of the plated through hole or the metal via 52. The flat boundary 56 is normal to the corresponding incoming circuit trace 53.

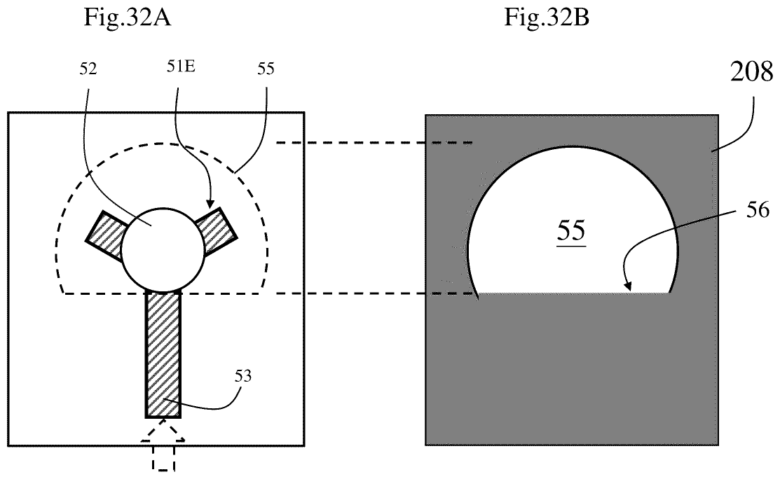

FIG. 32A˜32B shows a fifth design for the hole or via with reference to a corresponding clearance on the ground plane according to the present invention.

FIG. 32A shows two blade metal pads 51E, a plated through hole or a metal via 52, and an incoming circuit 53 connecting to the plated through hole or a metal via 52. The two blade metal pads 51E, in addition to the incoming circuit trace 53, are configured at 120 degrees to each other.

FIG. 32B shows a ground plane 208 configurated below the circular metal pad 51, in the Z direction, with an insulation layer in between. A clearance 55 is configured on the ground plane 208. The clearance 55 has a size greater than the plated through hole or a metal via 52; the clearance 55 overlaps the plated through hole or a metal via 52; and the clearance 55 has a flat boundary 56, that is tangent to but does not contacting a rim of the plated through hole or the metal via 52. The flat boundary 56 is normal to the corresponding incoming circuit trace 53.

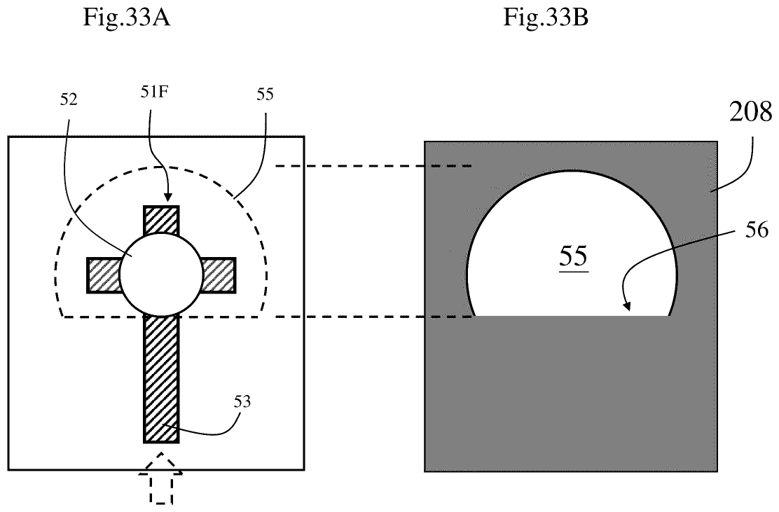

FIG. 33A˜33B shows a sixth design for the hole or via with reference to a corresponding clearance on the ground plane according to the present invention.

FIG. 33A shows three blade metal pads 51F, a plated through hole or a metal via 52, and an incoming circuit 53 connecting to the plated through hole or a metal via 52. The three blade metal pads 51F, in addition to the incoming circuit trace 53, are configured at 90 degrees to each other.

FIG. 33B shows a ground plane 208 configurated below the circular metal pad 51, in the Z direction, with an insulation layer in between. A clearance 55 is configured on the ground plane 208. The clearance 55 has a size greater than the plated through hole or a metal via 52; the clearance 55 overlaps the plated through hole or a metal via 52; and the clearance 55 has a flat boundary 56, that is tangent to but does not contacting a rim of the plated through hole or the metal via 52. The flat boundary 56 is normal to the corresponding incoming circuit trace 53.

While several embodiments have been described by way of example, it will be apparent to those skilled in the art that various modifications can be made without departing from the spirit of the appended claims.

### Numeral System

51 metal pad
52 via/hole
53 incoming circuit trace
55 clearance
56 flat boundary
100 ASIC
101 substrate
102 motherboard
103 Ethernet port
104 circuit board
105 differential pair circuit
105P parallel circuit trace
106˜107 metal pad
204, 204B, 204C circuit board
205 differential pair circuit
205B bottom circuit trace
205G ground trace
205P parallel circuit traces
205T top circuit trace
206, 206B metal pad
207, 207A, 207B, 207C, 207D, 207E metal pad
2071, 2072 metal pad
208 ground plane
209 insulation layer
212 turn connection
213B, 213T circuit layer
214 via
304, 304B, 304C, 304D circuit board
306, 306B, 306C circuit board stack
307 pad
308 bracket
311˜316 circuit layer
B10, B11, B12, B13 metal ball
B21, B22, B23 metal ball
B31, B32, B33 metal ball
B41, B42, B43 metal ball
C1˜C10 metal contacts
E1 left elevation
E2 right elevation
EOCB Electro-Optical Circuit Board, EOCB
HB1, HB2, HB3 hardboard
L1, L2, L3, L4 circuit layer
S1, S2 metal spring
NS narrow side
P11, P12, P13 pad
V, V10, V11, V12, V13, V15 via
WS wide side

What is claimed is:

1. A circuit board for connectors, comprising:
a circuit layer, which further comprises a plurality of parallel circuit traces, a plurality of left metal pads, and a plurality of right metal pads, wherein,
the plurality of parallel circuit traces extending horizontally;
each parallel circuit trace having a left end electrically coupled to a corresponding left metal pad;
each parallel circuit trace having a right end electrically coupled to a corresponding right metal pad;
the plurality of parallel circuit traces occupies a left elevation of E1; and
the plurality of right metal pads occupies a right elevation E2; wherein
the left elevation E1 is smaller than the right elevation E2.

2. The circuit board as claimed in claim 1, further comprising:
a plurality of metal vias configured on the left side of the circuit board; wherein each metal vias has its top end electrically couples with a corresponding left metal pad.

3. The circuit board as claimed in claim 2, further comprising
a plurality of metal balls configured on a bottom side of the circuit board; wherein each metal ball electrically couples with a bottom end of a corresponding metal via.

4. The circuit board as claimed in claim 3, wherein
a portion of the parallel circuit traces have their right ends arranged in one of the following ways: right-shifted in sequence, left-shifted in sequence, or a combination thereof.

5. The circuit board as claimed in claim 4, wherein
each trace width of the parallel circuit traces is equal.

6. The circuit board as claimed in claim 5, wherein
each space width between neighboring parallel circuit traces is equal.

7. The circuit board as claimed in claim 6, wherein
the space width is the same as the trace width.

8. The circuit board as claimed in claim 7, wherein
the left elevation is approximately half or less than the right elevation.

9. The circuit board as claimed in claim 8, wherein
the left elevation is approximately one-third or less than the right elevation.

10. The circuit board as claimed in claim 9, wherein
each parallel circuit trace is selected from the group consisting of signal trace, ground trace, and differential pair circuit trace.

11. The circuit board as claimed in claim 10, wherein
each parallel circuit trace having a left end electrically coupled to a corresponding metal via.

12. The circuit board as claimed in claim 11, wherein
the connection between the parallel circuit trace and the corresponding metal via is one of a direct connection and a turn connection.

13. The circuit board as claimed in claim 12, wherein
the turn for the connection is at approximately a 45-degree angle relative to the horizontal.

14. The circuit board as claimed in claim 13, wherein
for a differential pair circuit trace, the two corresponding metal vias are aligned and form an angle between 0 and 90 degrees relative to the horizontal.

15. The circuit board as claimed in claim 14, wherein
the two corresponding metal vias are aligned in one of: Y direction and X direction.

16. The circuit board as claimed in claim 15, for a differential pair circuit trace with a ground trace besides, further comprising:
a ground pad, electrically coupled with the corresponding ground trace; and
a ground via, electrically coupled with a corresponding ground pad.

17. The circuit board as claimed in claim 16, wherein
the ground pad is configured in a middle of the two metal pads; and
the ground via is configured in a middle of the two metal vias.

18. The circuit board as claimed in claim 17, wherein
the two metal vias and the ground via are aligned in an angle between 0 and 90 degrees with reference to a horizontal direction.

19. The circuit board as claimed in claim 18, wherein
the metal via is replaced by one of coaxial via, and plated through hole via.

20. The circuit board as claimed in claim 19, further comprising
an oval pad configured around an end of a corresponding metal via.

21. The circuit board as claimed in claim 20, wherein
the oval pad has a size larger than the end of the corresponding metal via, and
the oval pad pinches the corresponding metal via with its two waists.

22. The circuit board as claimed in claim 19, further comprising
single blade pad configured around an end of the metal via.

23. The circuit board as claimed in claim 22, wherein
the single blade is configured at a position opposite to a corresponding incoming circuit trace.

24. The circuit board as claimed in claim 19, further comprising
two blade pads configured around an end of the metal via.

25. The circuit board as claimed in claim 24, wherein
each pad is configured at 90 degrees with respect to a corresponding incoming circuit trace.

26. The circuit board as claimed in claim 24, wherein
each pad is configured at 120 degrees with respect to a corresponding incoming circuit trace.

27. The circuit board as claimed in claim 19, further comprising
three blade pads configured around an end of the metal via.

28. The circuit board as claimed in claim 27, wherein
each blade pad is configured at 90 degrees with each other.

29. The circuit board as claimed in claim 1, further comprising:
a ground plane configured below the circuit layer, with an insulation layer in between;
a first clearance formed on the ground plane; wherein
for a corresponding metal via,
the clearance has a size greater than the metal via;
the clearance overlaps the metal via; and
the clearance has a flat boundary tangent to but does not contacting a rim of the metal via.

30. The circuit board as claimed in claim 29, wherein
the flat boundary is normal to a corresponding incoming circuit trace.

31. The circuit board as claimed in claim 29, further comprising
a second clearance formed on the ground plane; wherein
for a corresponding rectangular metal contact,
the clearance has a size greater than the rectangular metal contact;
the clearance overlaps the rectangular metal contact; and
the clearance has a flat boundary overlapping a junction between the rectangular metal pad and an incoming circuit trace.

32. The circuit board as claimed in claim 1, wherein
the circuit board is shaped like a funnel.

33. The circuit board as claimed in claim 35, further comprising:
a plurality of metal springs, each metal spring is configured on a surface of a corresponding metal contact.

34. The circuit board as claimed in claim 33, wherein
the metal spring has a V-shaped portion, with a tip pointing away from the surface of the corresponding metal contact.

35. A connector, comprising:
a circuit board further comprising a plurality of metal contacts; and
a plurality of metal springs, each metal spring configured on a surface of a corresponding metal contact; wherein
each metal spring has V-shaped portion, with a tip point away from the surface of the corresponding metal contact.

36. The connector as claimed in claim 35, wherein
The metal spring has a shape like a lowercase sigma or a teaspoon.

37. A circuit board, comprising:
a circuit layer having a metal via;
a first incoming circuit trace electrically coupled to the metal via,
a ground plane configured beneath the circuit layer with an insulation in between; and
a first clearance formed on the ground plane; wherein
the first clearance has a size greater than and overlaps the metal via;
the first clearance has a flat boundary tangent to but does not contacting a rim of the metal via; and
the flat boundary is configured normal to the first circuit trace.

38. A circuit board as claimed in claim 37, wherein
the circuit layer further comprising a rectangular metal pad,
a second incoming circuit trace electrically coupled to the rectangular metal pad;
a second clearance formed on the ground plane; wherein
the second clearance has a size greater than and overlaps the rectangular metal pad;
the second clearance has a flat boundary overlapping a junction between the rectangular metal pad and the second incoming circuit trace.
